(19) United States
(12) Patent Application Publication
(10) Pub. No.: US 2002/0062792 A1
(43) Pub. Date: May 30, 2002

(54) Wafer support device and reactor system for epitaxial layer growth

(75) Inventors: Mark R. Boydston, Vancouver, WA (US); Gerald R. Dietze, Portland, OR (US); Oleg V. Kononchuk, Vancouver, WA (US); Rodney D. Scherschel, Vancouver, WA (US); Mengistu Yemane-Berhane, Vancouver, WA (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: SEH America, Inc., Vancouver, WA

(21) Appl. No.: 10/041,355

(22) Filed: Jan. 8, 2002

Related U.S. Application Data
(63) Continuation-in-part of application No. 09/567,659, filed on May 9, 2000.
Application No. 09/567,659 is a continuation-in-part of application No. 09/353,196, filed on Jul. 14, 1999, now abandoned.
Application No. 09/567,659 is a continuation-in-part of application No. 09/353,197, filed on Jul. 14, 1999.

(51) Int. Cl. C23C 16/00

(52) U.S. Cl. 118/728

(57) ABSTRACT

A wafer support device and an associated reactor system are provided which permit a wafer to be supported during the growth of a uniform epitaxial layer. The wafer support device includes a base and at least one contact member for supporting the wafer in a spaced relationship to the base. The base directs a portion of the gas through the space between the base and the back side of the wafer to facilitate the smooth flow of the gas. The wafer support device may also include a thermal mass proximate the edge of the wafer. The base may be formed of a material having greater thermal transparency than the material that forms the thermal mass such that the thermal mass will absorb and retain heat. Once heated, the thermal mass will therefore limit the heat that escapes from the edge of the wafer.

### CROSS-REFERENCE TO RELATED APPLICATIONS

This application is a continuation-in-part of application Ser. No. 09/567,659 filed May 9, 2000 which is a continuation-in-part both of application Ser. No. 09/353,196 filed Jul. 14, 1999 and application Ser. No. 09/353,197 filed Jul. 14, 1999, the disclosures of all of which are herein incorporated by reference.

### FIELD OF THE INVENTION

The present invention relates generally to wafer fabrication and, more specifically, to a reactor system and wafer support for use during epitaxial growth of a semiconductor material on a wafer.

### BACKGROUND OF THE INVENTION

In the semiconductor wafer manufacturing industry, thin epitaxial layers of semiconductor material, such as a silicon or gallium arsenide, are grown on a surface of a wafer. These epitaxial layers, commonly referred to as epilayers, form the material within which many modem integrated circuits are fabricated. In addition, many other devices, including optoelectric sensors, light emitting diodes, and micromachined mechanical devices, may be fabricated from epilayer material. As epilayers are fundamental building block for many technologies, it is critical that they be manufactured as efficiently and defect-free as possible, to reduce the cost and increase the quality of the epilayer.

Epilayers may be grown according to a variety of methods, including molecular beam epitaxy (MBE), vapor phase epitaxy (VPE), and liquid phase epitaxy (LPE). In a vapor phase epitaxial reactor, epilayer semiconductor constituents, such as silicon, gallium, arsenic, and germanium, and various dopants such as boron, phosphorous, arsenic, and antimony, are transported to the substrate surface as volatile species suspended in a vapor. Typically, the species are adsorbed onto the substrate at high temperature and diffuse across the surface to form the epilayer.

The VPE process takes place in a reactor including a heat energy source, such as radio frequency (RF) coils, heat lamps, or graphite resistance heating, and a susceptor. The susceptor typically is a solid graphite disk underlying and extending to the edge of the wafer and is substantially thicker than the wafer. One or more wafers are placed into the reactor directly on the susceptor, and the heat energy source is activated to heat the susceptor and the wafer. Where an RF energy source is used, the susceptor absorbs RF energy and heats the graphite disk which, in turn, heats the wafer. Where heat lamps are used, the susceptor absorbs heat energy and evenly distributes heat within the wafer, making the wafer less susceptible to temperature gradients within the reaction chamber.

After the wafer has been heated, gas containing the semiconductor constituents for epitaxial growth is introduced to the reactor through an inlet and flowed toward the wafer. Constituents are deposited on the front side of the wafer to form the epilayer. However, contact between the susceptor and the wafer inhibits gas flow to the back side of the wafer, such that constituents do not substantially reach the back side and similar growth does not occur on the back side.

Several problems exist with reactors having susceptors. First, the thermal mass of the susceptor must be heated within the reactor along with the wafer before the epitaxial growth process may begin. For each wafer, it is common for the reaction chamber to be heated and cooled several times during the epitaxial growth cycle. For example, after a silicon wafer is inserted into the reaction chamber, the temperature is typically raised for a hydrogen bake of the wafer, which removes silicon dioxide from the wafer. The chamber may be cooled for epilayer deposition, and is again cooled before unloading of the wafer. After deposition, the chamber typically is heated again, and etch gases, such as hydrogen chloride, are flowed through the chamber to remove semiconductor material from the chamber and susceptor.

When producing epitaxial wafers on a mass scale, heating up and cooling down the susceptor consumes significant amounts of time and energy. In addition, the susceptors require frequent cleaning as semiconductor materials build up on the surface of the susceptors during the epitaxial growth process. Without cleaning, deposits may flake off and contaminate the epilayer growth process. In addition, susceptors must be replaced as their surfaces degrade from repeated epilayer deposition and cleaning, further increasing the materials costs associated with wafer manufacture.

Use of a susceptor for epilayer growth also may induce thermal stresses within the wafer. For example, where RF coils are used to heat the susceptor, the back side of the wafer adjacent the susceptor typically will be hotter than the front side of the wafer during epilayer growth, causing the wafer to bow. Thermally induced strain will develop in the lattice of the bowed wafer as the wafer cools.

Compared to other fabrication procedures, epilayer growth takes place under closely controlled conditions. A prior step in the wafer manufacture process may leave contaminants or imperfections on the surface of the wafer. One effect of the epilayer growth process is to remove these contaminants and correct these imperfections. However, reactors that grow an epilayer on only one side of a wafer, such as reactors that use susceptors, do not remove contaminants or perfect the imperfections on the back side of the wafer. These imperfections and contaminants on the back side may adversely affect a downstream circuit fabrication, test, or measurement procedure.

Where only the front side of a wafer is being coated with an epilayer, there is a risk that dopants within the substrate of the wafer will escape from the back side of the substrate at high temperatures during the epitaxial growth process, enter the gas flow, and contaminate the epilayer growth process on the front side of the wafer. This contamination process is referred to as autodoping, and is highly undesirable.

By way of example and with reference to FIG. 1, a conventional epitaxial reactor is shown generally at 10, including a susceptor assembly shown at 12. A conventional reactor 10 includes a reaction chamber 14 flanked on an upper side by an upper heat lamp array 16 and on a lower side by a lower heat lamp array 18. Susceptor assembly 12 is positioned within reaction chamber 14, and is configured to support semiconductor wafer 20 within reaction chamber 14.

As shown in FIGS. 1 and 2, susceptor assembly 12 includes several components, each of which must be heated by the upper and lower heat lamp arrays as the reaction chamber is heated to a process temperature. Susceptor assembly 12 includes a susceptor 22, typically of graphite construction, which acts to absorb heat energy from lamps 16, 18 and to evenly distribute the heat energy to wafer 20 during epitaxial deposition. Susceptor 22 typically includes a depression 36 on its top surface. During epilayer growth, wafer 20 rests upon the susceptor, contacting the susceptor only at an outer edge 38 of the susceptor. As shown in FIG. 1, susceptor 22 rests directly upon posts 32 of tripod 30. Tripod 30 rests upon shaft 34, which is configured to rotate under the influence of a prime mover (not shown).

In operation, the reaction chamber is heated to a process temperature and a source gas containing semiconductor constituents is flowed from inlet 40 to outlet 42, across a front side 46 of wafer 20 on its way through the reaction chamber. Typically, the semiconductor constituents are absorbed onto the wafer surface at high temperature and diffuse across the surface to form the epilayer.

Susceptor assembly 12 also includes an annular structure 23, including mating L-shaped rings 24 and 26, each typically of graphite. The annular structure 23 is supported on posts 27 of a support 28, and is positioned around susceptor 22 such that the susceptor is free to rotate within the annular structure.

The annular structure 23 is used to insulate and control heat transfer at an outer edge of the wafer. Reactors with susceptors typically experience cooling along the perimeter of the wafer due to heat loss to the gas flow. The annular structure absorbs heat energy from the heat sources and helps prevent heat loss at the perimeter of the wafer, thereby keeping the temperature more uniform across the wafer and facilitating uniform epilayer growth.

However, susceptor 22, annular structure 23, and support 28 add thermal mass to the reaction chamber. For each wafer, these components must be heated and cooled multiple times during the epilayer growth process. In addition, these components periodically must be cleaned and/or replaced when deposits accumulate on the components from the epitaxial growth process. Therefore, use of these susceptor assembly components consumes great amounts of energy, time, and replacement materials.

In an attempt to remedy some of the shortcomings associated with conventional reactor systems that employed a susceptor to support a wafer, various susceptorless wafer supports have been developed. As the name suggests, these wafer supports do not include a susceptor. Instead, the wafer is generally supported by one or more contact members, each of which contacts only a small portion of the back side of the wafer with the remainder of the back side of the wafer being exposed to the gas flow through the reaction chamber. By way of example, one susceptorless wafer support includes a hub and three arms extending radially outward from the hub. Each arm either includes or carries a contact member for supporting the wafer. In a typical configuration, for example, each contact member extends upwardly from a respective arm to a tip that is configured to directly contact the back side of the wafer. In order to reduce the contact area with the wafer, the tip may be rounded or pointed. Thus, gas may flow around the arms of this wafer support and contact the back side of the wafer, other than those portions of the back side of the wafer blocked by the contact members.

Susceptorless wafer supports are advantageous since the thermal mass of the wafer support is much less than a conventional susceptor. Accordingly, the thermal mass that must be heated and cooled during each epitaxial growth cycle is reduced, thereby conserving time and energy. Additionally, by permitting gas flow over the majority of the back side of a wafer, susceptorless wafer supports permit a layer to be formed on the majority of the back side of the wafer. Once this layer is formed on the back side of the wafer, the possibility of autodoping is significantly reduced, thereby potentially improving the quality of the epitaxial layer deposited upon the front side of the wafer.

Unfortunately, susceptorless wafer supports suffer from several shortcomings. In this regard, the contact members directly contact the back side of the wafer, thereby preventing epitaxial deposition upon those portions of the back side of the wafer that are blocked by the contact members. While susceptorless wafer supports may be designed such that the tips of the contact members are relatively small so as to make contact with correspondingly small portions of the back side of the wafer, the deleterious effects upon the layers deposited on both the front and back side of the wafer is much broader. In this regard, contact of the tips of the contact members with the back side of the wafer tends to draw heat away from the wafer by a conductive heat transfer process, thereby causing a temperature gradient in the wafer.

Since the rate of epitaxial deposition upon the front and back sides of the wafer is at least partially dependent upon the temperature of the wafer, the temperature variations created by the contact members cause the epitaxial layer to grow at different rates across the front and back sides of the wafer. For example, the epitaxial growth rate is generally slower for those regions of the front side of the wafer that overlie the contact members than for other regions of the front side of the wafer. In addition, the contact members may interfere in radiation of heat energy from the lower heat energy source to the wafer, thereby causing a region of the wafer to receive less heat energy, and be cooler, than surrounding regions. This interference will result in changes in epilayer growth in the cooler portion, thereby producing a heat shadow in the resultant epilayer that may interfere with later circuit fabrication in the epilayer. As such, the flatness of the layers on both the front and back sides of the wafer is reduced as a result of the varying rates of deposition attributable to the temperature differences across the wafer. Additionally, the arms of a susceptorless wafer support may interrupt the gas flow across the back side of the wafer such that the gas no longer flows in a laminar manner as desired in most applications. As a result of the disruption of the gas flow, the deposition of the layer may further vary across the back side of the wafer.

It is generally desirable to deposit a relatively uniform and flat epitaxial layer upon at least the front side of a wafer. Thus, while susceptorless wafer supports are advantageous at least in terms of reducing the thermal mass that must be heated and cooled during the process of the depositing an epitaxial layer, it would still be desirable to develop an improved susceptorless wafer support that facilitated the deposition of layers having increased uniformity and flatness on both the front and back sides of the wafer.

### SUMMARY OF THE INVENTION

A wafer support device and an associated reactor system are therefore provided which permit a wafer to be supported during the growth of an epitaxial layer on the wafer in such a manner that the quality of the epitaxial layer, including the flatness of the epitaxial layer, may be improved. In this regard, the wafer support device promotes the smooth and relatively laminar flow of gas across both the front and back sides of the wafer. In addition, although at least some embodiments of the wafer support device include a thermal mass proximate the edge of the wafer for reducing heat loss from the edge of the wafer, the overall thermal mass of the wafer support device is limited such that the reaction chamber may be alternately heated and cooled in an efficient and timely manner.

According to one aspect of the present invention, an improved wafer support device is provided to support a wafer during the growth of an epitaxial layer on the wafer. The wafer support device includes a base and at least one contact member for supporting the wafer in a spaced relationship to the base. As such, the base underlies at least a majority of the wafer. In one advantageous embodiment, the base is at least as large as the wafer and the contact member(s) support the wafer such that the base underlies the entire wafer. The base serves to direct a portion of the gas through the space between the base and the back side of the wafer in a manner that facilitates the smooth and substantially laminar flow of the gas. To this end, the base may include a planar surface that faces the wafer. As a result of the smooth and even flow of the gas, the quality of the layer deposited upon the back side of the wafer, including the flatness of the epitaxial layer, may be improved. In order to limit the thermal mass that must be heated and cooled during the deposition of an epitaxial layer, the base is preferably comprised of a material that is relatively thermally transparent. For example, the base may be formed of quartz which heats and cools relatively rapidly.

A wafer support device may also include a thermal mass proximate the edge of the wafer and extending about at least a majority of the wafer and, more typically, about the entire wafer. The thermal mass is preferably formed of a material that is less thermally transparent than the base such that the thermal mass will absorb and retain heat. For example, the thermal mass may be formed of graphite and, more particularly, of graphite coated with silicon carbide. As such, once the thermal mass is heated, the thermal mass will serve to heat the edge of the wafer and to limit the heat that escapes from the edge of the wafer. Thus, the quality of the epitaxial layer deposited upon the wafer, including the flatness of the epitaxial layer, will be improved, particularly in those regions of the wafer proximate the edge of the wafer. While the thermal mass will require some time to heat and cool during the epitaxial deposition process, the wafer support device of this embodiment generally reduces the overall time required to heat and cool the reaction chamber by including other components that are relatively thermally transparent and may be heated and cooled in a more rapid manner.

In one embodiment, the contact member(s) extend inward from the thermal mass such that the combination of the thermal mass and the contact member(s) forms an apparatus for supporting and heating the edge of the wafer during growth of an epitaxial layer on the wafer. In this regard, the contact member(s) may also extend downward from the thermal mass relative to the wafer. As such, the contact member may contact the wafer along the edge of the wafer so as not to disrupt the flow of gas over the back side of the wafer and so as not to prevent the gas from contacting any point upon the back side of the wafer. In one embodiment, the thermal mass and the contact member(s) are formed monolithically of the same material. Thus, the contact member(s) may also be formed of a material, such as graphite or graphite coated with silicon carbide, that absorbs and retains heat and, as such, does not draw much, if any, heat away from the wafer during the epitaxial deposition process. While the wafer support device may include one or more discrete contact members, the wafer support device of one embodiment includes a single contact member that extends peripherally about the entire wafer.

In addition to the base and the contact member, the wafer support device may include at least one spacer extending outwardly from the base so as to carry the contact member. For example, the spacer(s) may extend between the base and either the thermal mass or the contact member(s) to space the thermal mass and the contact member from the base. Accordingly, the spacers serve to define the gap between the base and the back side of the wafer through which gas will flow during the epitaxial deposition process. In order to further improve the quality of the epitaxial layer deposited upon the wafer, the wafer support device may include a shaft for engaging the base such that rotation of the shaft correspondingly rotates the base, the contact member(s) and the thermal mass.

According to another aspect of the present invention, a reactor system is provided for growing an epitaxial layer on the wafer. In addition to the wafer support device, the reactor system generally includes a reaction chamber in which the wafer support device is disposed. A reaction chamber includes an inlet and an outlet through which a source gas flows during the epitaxial deposition process. Accordingly, relatively uniform layers may be deposited upon both the front and back sides of a wafer supported by a wafer support device of the present invention. Moreover, the reactor system is capable of heating and cooling the reaction chamber in a relatively efficient manner since the overall thermal mass of the wafer support device is limited.

### BRIEF DESCRIPTION OF THE DRAWINGS

Having thus described the invention in general terms, reference will now be made to the accompanying drawings, which are not necessarily drawn to scale, and wherein:

FIG. 1 is a cross-sectional view of a conventional epitaxial reactor including a susceptor;

FIG. 2 is a partial cutaway exploded perspective view of a susceptor assembly of the conventional epitaxial reactor of FIG. 1;

FIG. 3 is a cross-sectional view of a reactor system according to one embodiment of the present invention;

FIG. 4 is an exploded perspective view of a wafer support device according to one embodiment of the present invention;

FIG. 5 is an assembled perspective view of the wafer support device of FIG. 4;

FIG. 6 is a fragmentary side view of a portion of the wafer support device of FIGS. 4 and 5 depicting the support of the wafer provided by the contact member carried by the thermal mass;

FIG. 7 is a fragmentary plan view of a portion of the thermal mass of FIGS. 4-6 depicting an aperture for receiving a support in order to space the thermal mass from the base;

FIG. 8 is a fragmentary side view of a spacer according to the embodiment of the wafer support device depicted in FIGS. 4-6;

FIG. 9 is a cross-sectional side view of a wafer support device according to another embodiment of the present invention;

FIG. 10 is a plan view of the wafer support device of FIG. 9;

FIG. 11 is a fragmentary side view of a spacer and associated thermal mass support of the wafer support device of FIGS. 9 and 10; and

FIG. 12 is a fragmentary side view of a spacer and associated thermal mass support of another embodiment of a wafer support device according to the present invention.

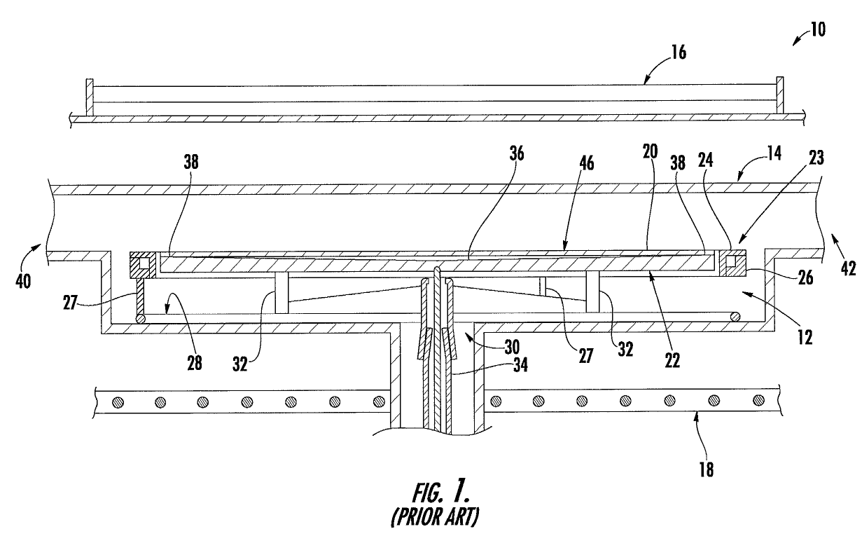

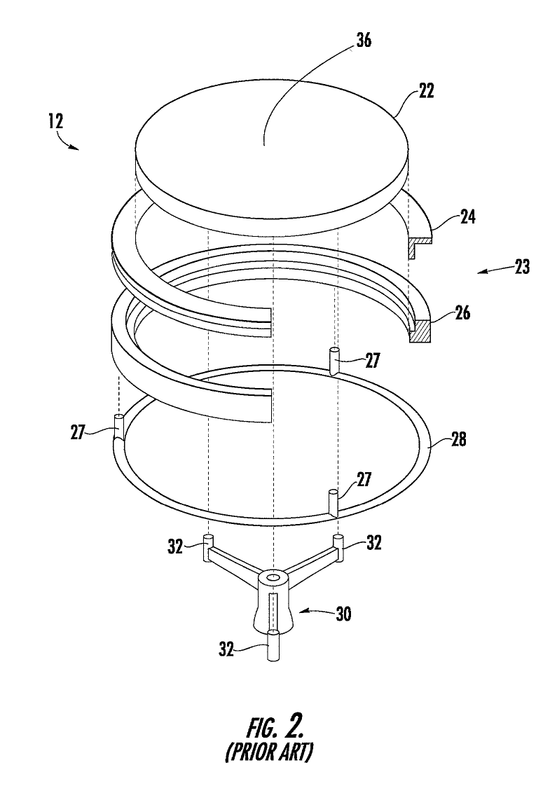

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

Turning now to FIG. 3, an epitaxial reactor system according to the present invention is shown generally at 50. Reactor system 50 includes an upper heat energy source 52 and a lower heat energy source 54 positioned on opposing sides of a reaction chamber 56. Typically, upper heat energy source includes a plurality of infrared (IR) heat lamps 62 or the like positioned in an array extending across the top of reaction chamber, and lower heat energy source includes a plurality of IR heat lamps 64 or the like positioned in an array rotated 90 degrees from heat lamps 62 and extending across the bottom of reaction chamber. Alternatively, the upper and lower heat energy sources may be RF coils, or another type of heat source. Wafer 58 is heated by heat energy radiating from the upper heat source directly to a front side 66 of the wafer, and from the lower heat energy source directly to a back side 68 of the wafer.

The epitaxial reactor system 50 also includes a wafer support device 70 disposed at least partially within the reactor chamber 56 for supporting the wafer 58 within the reaction chamber. The wafer support device includes a base 72 mounted upon or otherwise rotatably connected to a shaft 74. While the base may be formed integrally with the shaft, the base is typically connected to one end of the shaft by the insertion of a tapered end of the shaft into a similarly tapered cup or other receptacle 76 on a lower side of the base. The other end of the shaft is generally connected to a rotation and translation mechanism that is configured to rotate, raise and lower the shaft in the wafer support device within the reaction chamber. Rotation of the wafer ensures that radiant heat energy and source gasses containing reactants are evenly distributed to all regions of the wafer. Alternatively, the shaft and wafer support device may be configured only to rotate, or to move up and down, or the shaft and wafer support device may not move at all depending upon the design of the reactor system.

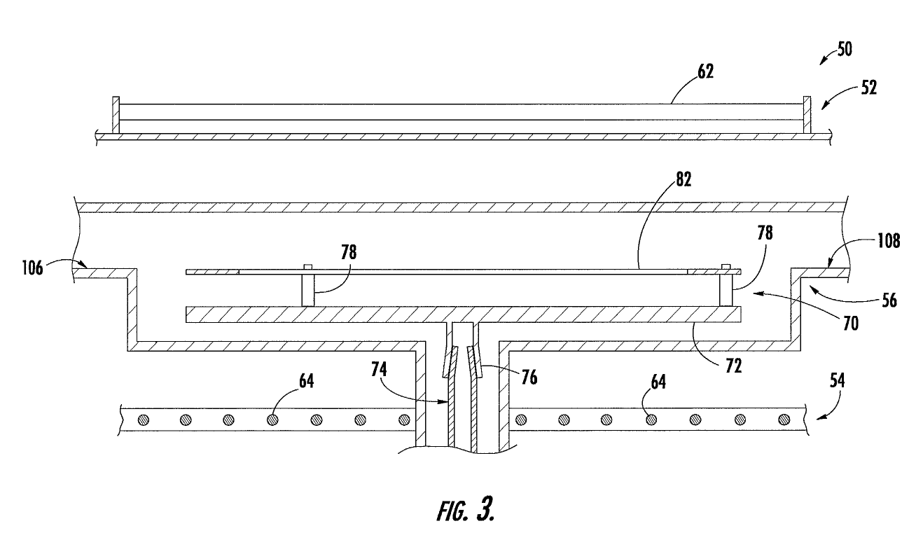

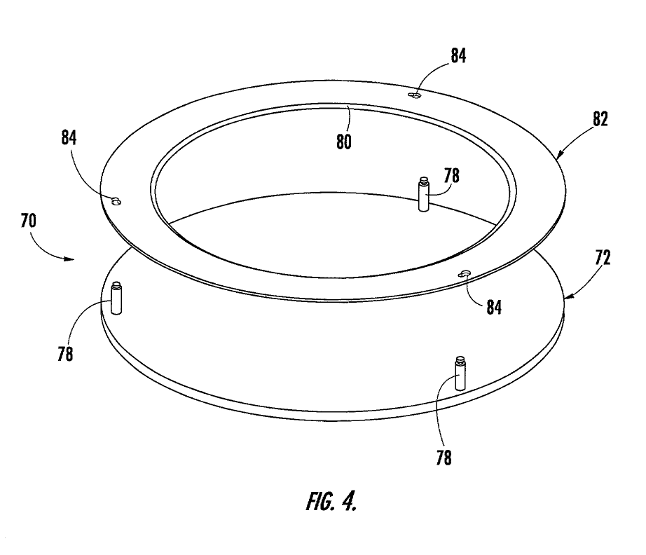

As shown in more detail in FIGS. 4 and 5, the wafer support device 70 also includes at least one and, more typically, a plurality of spacers 78 that extend outwardly from the base 72. While the wafer support device can include any number of spacers, the wafer support device of the illustrated embodiment includes three spacers positioned equidistant from the center of the base and at equal angular increments thereabout. Typically, the spacers are formed of the same material as the base and, as such, may be formed integrally with the base. The wafer support device also includes at least one contact member 80 carried or otherwise supported by the spacers. The contact member(s) are adapted to contact the wafer and to correspondingly support the wafer 58. In this regard, the contact member(s) support the wafer in a spaced relationship with respect to the base as shown in FIG. 6. As described hereinbelow, the gap defined between the base and the wafer facilitates the smooth flow of gas about the wafer and, in particular, across the back side of the wafer.

In order to further facilitate the relatively even flow of gas across the back side of the wafer 58, the contact member(s) 80 support the wafer relative to the base 72 such that the base underlies at least a majority of the wafer. In one advantageous embodiment, the base is at least as large as a wafer and, more preferably, slightly larger than the wafer and the contact member(s) support the wafer such that the base underlies the entire wafer. It should be noted, however, that while the wafer support device of the illustrated embodiment includes a circular base, the base may have other shapes, if so desired. Additionally, the surface of the base that faces the wafer is generally planar so as not to disrupt or otherwise perturb the flow of the gas through the space defined between the base and the wafer. In order to facilitate the smooth flow of gas across the back side of the wafer, the number and the size of the spacers 78 are also preferably limited and the spacers preferably have a rounded shape in cross-section such as the cylindrical spacer in the illustrated embodiment. As such, the flow of gas is generally approximately laminar such that all portions of the back side of the wafer are exposed to substantially equal amounts of the gas, thereby fostering the deposition of a uniform layer of increased flatness across the back side of the wafer.

As illustrated in FIGS. 4-6, the wafer support device of one embodiment may also include a thermal mass 82, such as a heat absorbing ring. The thermal mass is disposed proximate an edge of the wafer 58 and extends about at least a majority of the wafer. Advantageously, the thermal mass extends peripherally about the entire wafer. The thermal mass is formed of a material that absorbs and retains heat so as to heat the edge of the wafer and to correspondingly reduce the heat that otherwise would escape from the edge of the wafer. Thus, the thermal mass of one embodiment is formed of graphite and, more particularly, graphite coated with silicon carbide (SiC). Alternatively, the thermal mass could be formed entirely of SiC or of silicon.

In this embodiment, the contact member(s) 80 may extend inward from the thermal mass 82 in order to engage and support the wafer 58. Thus, the contact member(s) and the thermal mass may be integrally formed of the same material so as to form a monolithic structure. As such, the contact member(s) of this embodiment would also preferably be formed of a material that absorbs and retains heat. Thus, although the contact member(s) contact the wafer, the contact member(s) will not draw substantial heat from the wafer since the contact member(s) will be at approximately the same temperature as the wafer, thereby significantly limiting any temperature gradients introduced in the wafer.

In one advantageous embodiment in which the thermal mass 82 has a ring shape and extends peripherally about the entire wafer 58, the contact member 80 may similarly have a ring shape and may extend radially inward from the entire inner edge of the thermal mass. Thus, the contact member essentially forms an annular shelf upon which the edge of the wafer will rest. It should be understood, however, that the contact member(s) may have other configurations that may include a plurality of contact member(s) extending inwardly from the thermal mass at various locations spaced apart thereabout.

In addition to extending radially inward from the thermal mass 82, the contact member(s) 80 also preferably extend downward from thermal mass relative to the wafer 58 as shown in FIG. 6. In this regard, the contact member(s) extend downward from a point above the bottom side of the wafer to a point below the bottom side of the wafer. The downwardly sloping contact member of this embodiment is configured to contact an outer edge of the wafer. The outer edge of the wafer typically includes top and bottom beveled portions and vertical portions. The bevels are cut at an angle θ relative to the horizontal. The contact member or, at least, the upper surface portion of the contact member is angled downward at an angle δ relative to the horizontal, such that angle δ is greater than zero degrees and less than angle θ. Thus, contact member contacts the wafer at one point of contact, i.e., at the corner between the bottom beveled portion and the back side of the wafer, thereby reducing the thermal variance caused by the wafer support on epilayer growth on the wafer.

Typically, angle θ is about 22 degrees, and angle δ is between about zero and 22 degrees. In one preferred embodiment of the invention, angle δ is between zero and 15 degrees. In another preferred embodiment of the invention, angle δ is between about zero and 10 degrees, and in a particularly preferred embodiment, angle δ is about 4 degrees. It has been found that in these ranges, the wafer 58 tends to center itself upon the three contact members 80 when dropped by a paddle or other loading device onto the contact members. The wafer vibrates slightly as it hits the contact members, and tends towards a centered position because of the inward slope of the contact members. Thus, successive wafers may be positioned in substantially the same position during the epilayer growth process, thereby assuring a uniform quality in the epilayers grown on the wafers.

The contact members 82 are preferably designed such that, once the wafer 58 is seated, the upper surface of the wafer will not protrude substantially above or below the upper surface of the thermal mass 82. In other words, once the wafer is seated, the upper surface of the thermal mass will preferably be coplanar with the wafer to facilitate the flow of gas thereover. In addition, a slight gap remains between the edge of the wafer and the inner edge of the thermal mass to facilitate wafer handling and placement upon the wafer support device 70.

While the thermal mass 82 and the contact member(s) 80 are generally formed of a material that absorbs and retains heat, the base 72 and the spacers 78 are preferably formed of a material that is more thermally transparent (at least at the wavelength at which the wafer support device 70 is being heated) than the material that forms the thermal mass. In other words, the material forming the thermal mass will absorb more heat, on average, than the material forming the base and the spacers. The base and the spacers are therefore substantially thermally transparent at the wavelength at which the wafer support device is being heated, such as at IR wavelengths.

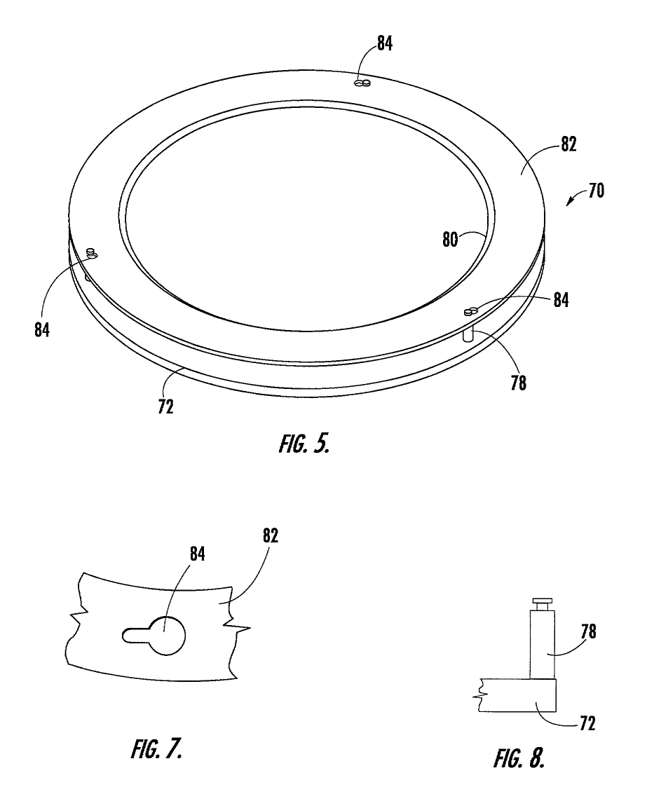

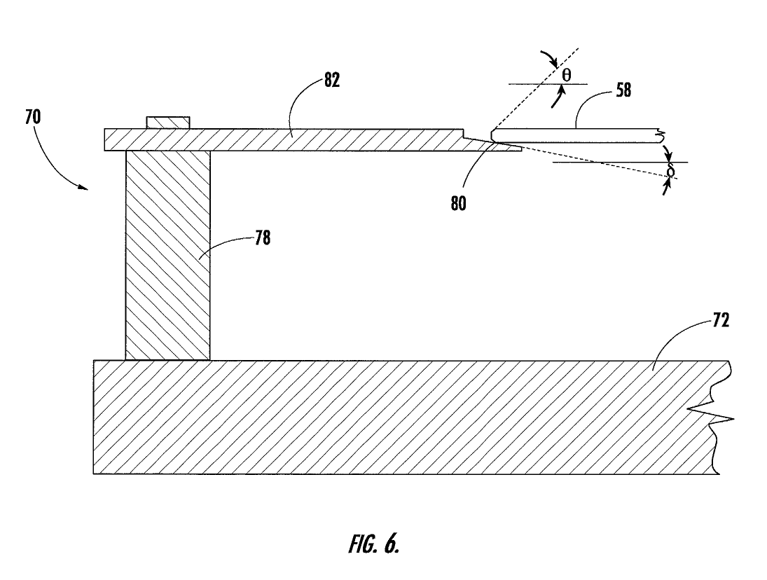

Since the base 72 and the thermal mass 82 are typically formed of different materials, the base and the thermal mass cannot be formed monolithically. As such, the thermal mass is typically adapted to be mounted upon and connected to the spacers 78. While the thermal mass may be connected to the spacers in various manners, the thermal mass of one embodiment defines a plurality of apertures 84 for receiving and engaging distal portions of respective spacers. In the illustrated embodiment, for example, the distal portion of each spacer has a reduced diameter relative to the remainder of the cylindrical spacer. See, for example, FIG. 8. In addition, one or more of the spacers may include a circumferential rib or knob that extends radially outward and is located along the distal portion at some distance from the remainder of the cylindrical spacer. In this embodiment and as depicted more clearly in FIG. 7, each aperture defined by the thermal mass includes an enlarged portion and at least one smaller lobe extending outward from the enlarged portion. The enlarged portion is sized to receive the distal portion of a respective spacer including the knob. However, the enlarged portion is also sized to be smaller than the remainder of the spacer such that the bottom side of the thermal mass can rest upon the shoulder defined by the transition of the spacer between the distal portion and the remainder of the cylindrical spacer. The lobe of the aperture is also sized to be slightly larger than the distal portion of the respective spacer. However, the lobe is smaller than both the knob carried by the distal portion and the remainder of the cylindrical spacer. In addition, the distance, in an axial direction, between the knob carried by the distal portion and the shoulder between the distal portion and the remainder of the cylindrical spacer is slightly greater than the thickness of the thermal mass. As such, following insertion of the distal end of each spacer through the enlarged portion of a respective opening, the thermal mass and/or the base may be rotated relative to one another such that the distal portion of each spacer is moved into the lobe of the respective opening. As a result of the relative sizes of the distal portion and the thermal mass, the thermal mass and the base will be engaged with the thermal mass held between the knob carried by the distal portion and the shoulder between the distal portion and the remainder of the cylindrical spacer. Subsequently, the thermal mass may be separated or removed from the base for replacement, cleaning or the like by reversing the assembly process.

In order to prevent the connection between the thermal mass 82 and the base 72 from loosening during rotation of the wafer support device 70 during an epitaxial deposition process, the lobe of the aperture 84 preferably extends away from the enlarged section in the opposite direction from that in which the wafer support device will rotate. In other words, if the wafer support device is adapted to rotate in a counterclockwise direction, the lobe preferably extends in a clockwise direction from the enlarged section. Although not necessary for the practice of the present invention, a retention member, such as a thumbtack shaped quartz member, may be inserted into the enlarged portion of the aperture after the thermal mass and the base have been rotated relative to one another so as to move the distal portion of the spacer into the lobe, thereby more securely retaining the spacer within the lobe.

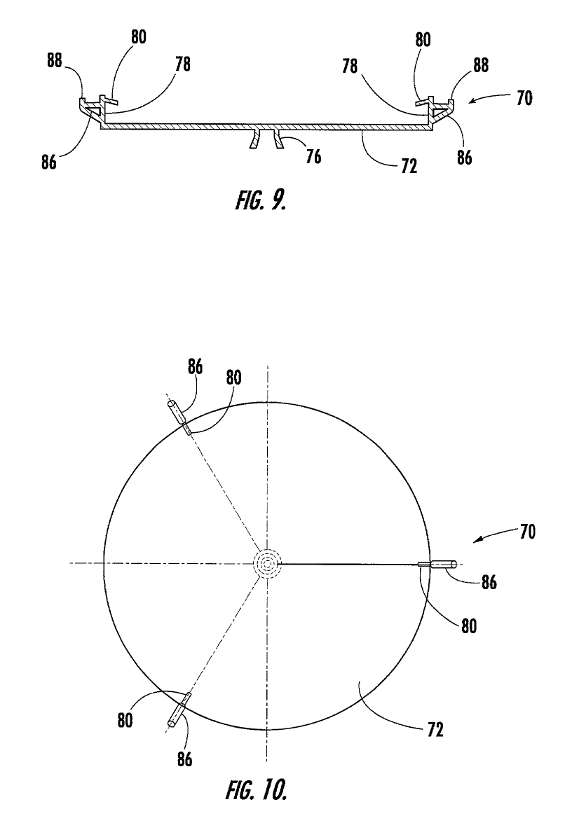

Although the wafer support device 70 described above offers many advantages, the wafer support device of the present invention may be configured in other manners, if so desired. As shown in FIGS. 9 and 10, for example, the wafer support device of another embodiment again includes a base 72, at least one spacer 78 extending outwardly from the base and at least one contact member 80 supported by the spacers(s) for supporting the wafer 58 in a spaced relationship to the base. As described above, the base underlies at least a majority of the wafer and, more typically, the entire wafer. While the contact member may be annular and extend circumferentially about the entire wafer as described above, the wafer support device of the illustrated embodiment includes a plurality of contact members, one of which is carried by each spacer for supporting the wafer at a plurality of discrete locations about the edge of the wafer. In particular, the wafer support device of the illustrated embodiment includes three spacers spaced at equal angular increments with each spacer carrying a respective contact member. As described above, each contact member extends radially inward from the respective spacer, preferably at a downward angle relative to the wafer so as to contact an edge of the wafer.

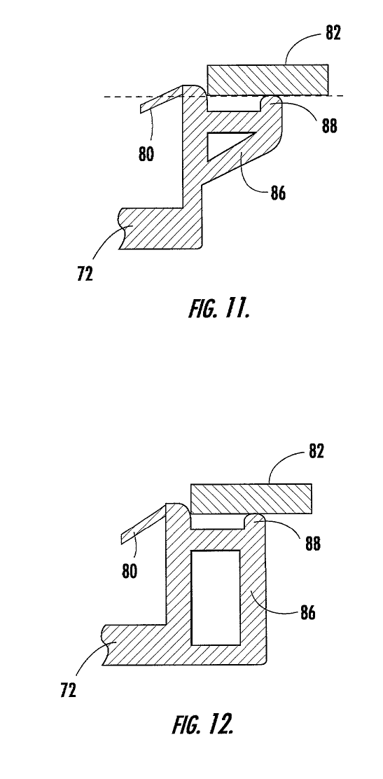

The wafer support device 70 of this embodiment can also include a thermal mass support 86 carried by the spacer(s) 78. As illustrated in FIG. 11, each spacer preferably carries a respective thermal mass support. Each thermal mass support extends radially outward from the respective spacer and includes an upper surface or, more preferably, an upstanding projection 88 for contacting the lower surface of the thermal mass 82 and for supporting the thermal mass. As such, a thermal mass having a ring-like or other annular structure may be placed upon the thermal mass supports carried by the respective spacers such that the thermal mass is positioned to extend circumferentially around the wafer 58. As described above, the thermal mass and the wafer are preferably supported such that the upper surface of the thermal mass is either coplanar with or protrudes above the upper surface of the wafer once the wafer is seated upon the contact members 80 to facilitate gas flow across the upper surface of the wafer. While the relationship between a contact member and the upstanding projection of a thermal mass support may vary depending upon the relative thicknesses of the wafer and the thermal mass, the wafer support device of one embodiment is designed such that the uppermost portion of the upstanding projection of each thermal mass support lies in the same plane, such as in the same horizontal plane, as the midpoint of the respective contact member. As such, the upper surface of the thermal mass in this embodiment is maintained coplanar with or above the upper surface of the wafer. To reduce conductive heat transfer between the thermal mass and the thermal mass support, the upstanding projection preferably has a rounded or pointed shape to reduce or minimize the contact area with the thermal mass. In addition, the uppermost portion of the spacers is also preferably rounded to facilitate gas flow. Additionally, while the thermal mass support of the embodiment depicted in FIG. 11 has a triangular shape, the thermal mass support may have other shapes, such as a rectangular shape as shown in FIG. 12.

Regardless of the configuration, the wafer support device 70 is disposed within a reaction chamber 56. The reaction chamber includes an inlet 106 and an outlet 108. The inlet is configured to receive a gas mixture from a gas source (not shown) and direct the flow of the gas mixture around wafer 58 to the outlet 108. The outlet is configured to transport the gas mixture to an exhaust system (not shown). Typically, the gas mixture includes a source gas containing epilayer semiconductor constituents, such as silicon, gallium, arsenic, and germanium. The gas mixture may also include a dopant gas including a dopant constituent, such as boron, phosphorous, arsenic, or antimony. These semiconductor and dopant constituents are transported to the wafer surface as volatile species suspended in the gas mixture. Typically, the constituents are adsorbed onto the substrate at high temperature and diffuse across the surface to form the epilayer.

Where it is desired to etch material from the wafer 58, wafer support device 70, or reaction chamber 56, the gas mixture may also include an etch gas, such as hydrogen chloride. It is also common for the gas mixture to include a carrier gas, such as hydrogen, which acts as a diluent within the gas mixture.

In one embodiment, inlet 106 and outlet 108 are horizontally disposed on opposite sides of reaction chamber 56, and wafer support 70 is configured to hold wafer 58 intermediate the inlet and the outlet, such that the gas mixture flows from the inlet, around the wafer, and to the outlet. During this gas flow, the gas mixture flows to each of the front side and the back side of the wafer. The wafer may be raised or lowered within the reaction chamber to adjust gas flow around the wafer; for example, the wafer may be raised to increase gas flow to the back side of the wafer. To reach the back side of the wafer, the gas mixture flows through the space between the base 72 and the wafer.

As described above, the wafer support device 70 is advantageously configured to support the wafer 58 adjacent an outer edge of the wafer. This manner of support reduces imperfections to the underside of wafer caused by supporting the wafer by direct contact with the backside. When used in combination with a thermal mass 82 to stabilize heat transfer from the outer edge of the wafer, fewer epilayer imperfections result.

According to the present invention, a method may be practiced for susceptorless epitaxial growth of a layer of semiconductor material on a wafer 58. The method includes placing the wafer within reaction chamber 56 and supporting the wafer directly on a contact member(s) 82 of wafer support device 70. The method further includes heating the wafer to a predetermined temperature without also heating a susceptor. Typically, the heat energy is radiated directly to the front and back sides of the wafer.

Reaction chamber 56 is heated by heat energy sources 52, 54 until wafer 58 reaches a predetermined process temperature at which it is desired that epilayer growth occur. The process temperature typically is between 900 and 1200 degrees Celsius. Since at least the base 72 and spacers 78 are formed of a material that is substantially thermally transparent and may be correspondingly heated and cooled in a relatively rapid fashion, the reaction chamber may be more rapidly heated and cooled than at least some conventional reaction chambers that include a larger thermal mass. As such, the time and energy required to heat and cool the reaction chamber during an epitaxial deposition process may be reduced in accordance with the present invention.

The method also includes flowing a source gas including semiconductor constituents across the wafer 58 to facilitate epilayer growth on a surface of the wafer. In addition to the flow of the source gas across the front side of the wafer, source gas is flowed, typically in a substantially laminar manner, through the gap defined between the base 72 and the back side of the wafer. The method may also include flowing a dopant gas, etch gas, and/or carrier gas to front and back sides of the wafer with the gases reaching the back side through the gap defined between the base and the back side of the wafer. Typically, the gases are simultaneously flowed to the front and back side of the wafer. Alternatively, the gases may be flowed alternately to a front side and a back side of the wafer, or flowed only to one of the front or back sides of the wafer.

Over time, deposits from the epilayer growth process build upon the components within reaction chamber 56. Such deposits may contaminate a growing epilayer, and must be removed periodically, such as by flowing an etch gas through the reaction chamber.

To distribute heat energy and gases flowing through reaction chamber 56 to wafer 58 evenly, the method may include rotating the wafer within the reaction chamber during growth of the epitaxial layer. The method may also include moving the wafer up and down within the reaction chamber during growth of the epitaxial layer to adjust the heat and/or gas mixture reaching a region of the wafer.

The method may also include deposition of a gettering layer on the back side of the wafer 58 during the epilayer deposition cycle. Gettering is a natural process by which defects in the crystal lattice attract impurities within the semiconductor material. The impurities are attracted to the defects due to the strain the defects create in the crystal lattice. As a result, impurities tend to precipitate around the defects. The method may include intentionally creating defects, or gettering sites, in the crystal lattice to attract contaminants away from the epilayer. For example, the method may include depositing a polysilicon layer on the back surface of the wafer to create strain within the crystal lattice.

According to the present invention, epitaxial growth may occur in a reactor system 56 without the susceptor utilized by conventional reactors. Therefore, the reaction chamber may be heated and cooled more quickly, with less energy, and epilayer growth may be achieved in a shorter cycle time per wafer, resulting in a finished epitaxial wafer of reduced cost. In addition, semiconductor deposition on reactor components and contamination therefrom is significantly reduced. It is believed that lower quantities of source gases are required by the present invention, because incidental deposition on other reactor components is reduced. The wafer support device 70 of the present invention also facilitates the smooth and substantially laminar flow of gas about the wafer 58 and, in particular, across the back side of the wafer. As such, the wafer support device of the present invention facilitates the deposition of a more uniform layer, such as a polysilicon layer or an epitaxial layer having increased flatness. Additionally, the wafer support device, 70, of the present invention creates an effective barrier to autodoping, a condition whereby front surface resistance uniformity is compromised by backside dopants. Further, by contacting the wafer only at the edge of the wafer and, in some embodiments, by utilizing a thermal mass 82 extending peripherally about the wafer, the uniformity of the epitaxial layer is further improved by reducing, if not eliminating, temperature gradients introduced into the wafer as a result of contact with the back side of the wafer and/or heat loss from the edge of the wafer. Moreover, by maintaining a uniform temperature across the wafer in accordance with the present invention, the wafer slip and/or wafer crowning may advantageously be reduced, if not eliminated.

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A wafer support device to support a wafer during growth of an epitaxial layer on the wafer, the wafer support device comprising:
a base;
at least one contact member for supporting the wafer in a spaced relationship to said base such that said base underlies at least a majority of the wafer; and
a thermal mass proximate an edge of the wafer and extending about at least a majority of the wafer,
wherein said base is formed of a material having greater thermal transparency than the material that forms said thermal mass.

2. A wafer support device according to claim 1 wherein said base is at least as large as the wafer, and wherein said at least one contact member supports the wafer such that said base underlies the entire wafer.

3. A wafer support device according to claim 1 wherein said base comprises a planar surface facing the wafer.

4. A wafer support device according to claim 1 wherein said thermal mass extends peripherally about the entire wafer.

5. A wafer support device according to claim 1 wherein said at least one contact member extends inward from said thermal mass.

6. A wafer support device according to claim 5 wherein said at least one contact member also extends downward from said thermal mass relative to the wafer.

7. A wafer support device according to claim 5 wherein said at least one contact member and said thermal mass are monolithic.

8. A wafer support device according to claim 1 wherein said at least one contact member extends peripherally about the entire wafer.

9. A wafer support device according to claim 1 further comprising at least one spacer between said base and at least one of said thermal mass and said at least one contact member for separating said thermal mass and said at least one contact member from said base.

10. A wafer support device according to claim 1 further comprising a shaft for engaging said base such that rotation of said shaft correspondingly rotates said base, said at least one contact member and said thermal mass.

11. A wafer support device according to claim 1 wherein said base is comprised of quartz and said thermal mass is comprised of graphite.

12. A wafer support device according to claim 11 wherein said thermal mass is comprised of graphite coated with silicon carbide.

13. An apparatus for supporting and heating an edge of a wafer during growth of an epitaxial layer on the wafer, the apparatus comprising:
a thermal mass proximate the edge of the wafer and extending about at least a majority of the wafer; and
a contact member extending both inward and downward relative to the wafer from said thermal mass for contacting the edge of the wafer and correspondingly supporting the wafer.

14. An apparatus according to claim 13 wherein said thermal mass extends peripherally about the entire wafer.

15. An apparatus according to claim 13 wherein said contact member and said thermal mass are monolithic.

16. An apparatus according to claim 13 wherein said contact member extends peripherally about the entire wafer.

17. An apparatus according to claim 13 wherein said thermal mass is comprised of graphite.

18. An apparatus according to claim 17 wherein said thermal mass is comprised of graphite coated with silicon carbide.

19. A wafer support device to support a wafer during growth of an epitaxial layer on the wafer, the wafer support device comprising:
a base;
at least one spacer extending outwardly from said base; and
a contact member carried by said at least one spacer and extending both inward and downward relative to the wafer for contacting the edge of the wafer and correspondingly supporting the wafer.

20. A wafer support device according to claim 19 wherein said base is at least as large as the wafer, and wherein said contact member supports the wafer such that said base underlies the entire wafer.

21. A wafer support device according to claim 19 wherein said base comprises a planar surface facing the wafer.

22. A wafer support device according to claim 19 wherein said contact member extends peripherally about the entire wafer.

23. A wafer support device according to claim 19 further comprising a thermal mass supported by said at least one spacer in a spaced relationship to said base, said thermal mass proximate an edge of the wafer and extending about at least a majority of the wafer, said base formed of a material having greater thermal transparency than the material that forms said thermal mass.

24. A wafer support device according to claim 23 wherein said contact member extends both inward and downward from said thermal mass, and wherein said thermal mass and said contact member are monolithic.

25. A wafer support device according to claim 23 wherein said thermal mass extends peripherally about the entire wafer.

26. A wafer support device according to claim 23 wherein said base is comprised of quartz and said thermal mass is comprised of graphite.

27. A wafer support device according to claim 26 wherein said thermal mass is comprised of graphite coated with silicon carbide.

28. A wafer support device according to claim 19 further comprising a shaft for engaging said base such that rotation of said shaft correspondingly rotates said base, said at least one spacer and said contact member.

29. A reactor system for growing an epitaxial layer on a wafer, the reactor system comprising:
a reaction chamber including an inlet and an outlet through which a source gas flows; and
a wafer support device disposed with said reaction chamber to support the wafer during growth of an epitaxial layer on the wafer, the wafer support device comprising
a base underlying at least a majority of the wafer in a spaced relationship thereto; and
a thermal mass proximate an edge of the wafer and extending about at least a majority of the wafer, said thermal mass disposed in a spaced relationship to said base,
wherein said base is formed of a material that has greater thermal transparency than the material that forms said thermal mass.

30. A reactor system according to claim 29 wherein said base is at least as large as the wafer such that said base underlies the entire wafer.

31. A reactor system according to claim 29 wherein said base comprises a planar surface facing the wafer.

32. A reactor system according to claim 29 wherein said thermal mass extends peripherally about the entire wafer.

33. A reactor system according to claim 29 further comprising a contact member extending inward from said thermal mass for supporting the wafer in a spaced relationship to said base.

34. A reactor system according to claim 33 wherein said contact member also extends downward from said thermal mass relative to the wafer.

35. A reactor system according to claim 33 wherein said contact member extends peripherally about the entire wafer.

36. A reactor system according to claim 29 further comprising at least one spacer between said base and said thermal mass for separating said thermal mass from said base.

37. A reactor system according to claim 29 further comprising a shaft for engaging said base such that rotation of said shaft correspondingly rotates said base and said thermal mass.

38. A reactor system according to claim 29 wherein said base is comprised of quartz and said thermal mass is comprised of graphite.

39. A reactor system according to claim 38 wherein said thermal mass is comprised of graphite coated with silicon carbide.
